(19) United States
(12) Patent Application Publication
(10) Pub. No.: US 2011/0033974 A1
(43) Pub. Date: Feb. 10, 2011

(54) METHOD FOR FABRICATING HOLLOW NANOTUBE STRUCTURE

(76) Inventors: Shui-Jinn WANG, Tainan City (TW); Der-Ming Kuo, Pingtung County (TW); Wei-Chih Isai, Chiayi County (TW); Chih-Ren Tseng, Changhua County (TW)

Correspondence Address: Muncy, Geissler, Olds & Lowe, PLLC, 4000 Legato Road, Suite 310, FAIRFAX, VA, 22033, US

(21) Appl. No.: 12/851,804

(22) Filed: Aug. 6, 2010

(30) Foreign Application Priority Data
Aug. 6, 2009 (TW) 098126550

(51) Int. Cl. H01L 21/36; H01L 21/441

(52) U.S. Cl. 438/104; 438/608; 977/890; 438/694; 257/43; 257/E21.461; 257/E21.477

(57) ABSTRACT

A method for fabricating a hollow nanotube structure is disclosed. The method includes the steps of providing a substrate, developing a plurality of nanowires on the substrate with a predetermined size on the seed layer at relatively low temperature by a hydro-thermal growth method, forming an outer covering layer on the surfaces of the nanowires, selectively etching an upper end of the outer coating layer to expose an upper end of the nanowires and removing the nanowires to remain the hollow outer coating layer to form a plurality of hollow nanotubes. The method can simplify the nanotube manufacturing process, increase the dimension precision of the nanotubes and enhance the photoelectric properties of micro-electro-mechanical elements.

### CROSS REFERENCE TO RELATED APPLICATIONS

This Non-provisional application claims priority under 35 U.S.C. §119(a) on Patent Application No(s). 98126550 filed in Taiwan, Republic of China on Aug. 6, 2009, the entire contents of which are hereby incorporated by reference.

### BACKGROUND OF THE INVENTION

1. Field of Invention

The present invention relates to a method for fabricating a hollow nanotube structure and, in particular, to a method for fabricating a hollow nanotube structure by forming nanowires and an outer covering layer.

2. Related Art

Recently, to satisfy the requirements of micro-electro-mechanical (MEM) and detecting elements, researchers keep working on developing and improving various nanostructures. In addition, proper insulation material (e.g. oxides), semiconductor material or conductive material is applied in the fabrication of various nanowires or hallow nanotube structures. For example, some nanomaterials including SiO₂, TiO₂, ZnO, InP, Si, GaN, Ni, Pt or Au can be used in the fabrication of metal nanowires. On the other hand, carbon or SiO₂ can also be used to fabricate hallow nanotubes. The aforementioned nanowires or hallow nanotube structure can provide various unique physical and chemical properties for researchers to design micro-electro-mechanical and detecting elements with different kinds of functions.

Currently, conventional methods for fabricating hallow nanotubes include growing by high-temperature furnace, electrophoretic deposition (EPD) with using catalyst or substrates, pulse laser deposition (PLD), metal-organic chemical-vapor deposition (MOCVD), atomic-layer deposition (ALD), thermal evaporation or surface sol-gel (SSG).

However, the conventional methods require expensive equipments and complex fabricating techniques such that the production cost of the conventional manufacturing process is relatively high. In addition, most of the conventional methods should be performed at high temperature such that these processes can not be applied to micro-electro-mechanical elements without thermal resistance. Moreover, the fabrication of derivative elements becomes more difficult and the photoelectrical properties of elements are affected. The most common method for fabricating nanotubes is to process proper material directly for forming the hollow nanotube structure. However, some nanomaterials cannot form hallow nanotube structure directly, so that the development potential of these nanomaterials in this field is limited.

Therefore, it has been desired to provide a method for fabricating a hollow nanotube structure that can solve existing problems of conventional techniques.

### SUMMARY OF THE INVENTION

The main objective of the present invention is to provide a method for fabricating a hollow nanotube structure. The method includes the steps of developing nanowires, covering the nanowires with an outer covering layer, and removing the nanowires inside the outer covering layer. Consequentially, the hollow nanotubes can be formed by the remaining outer covering layer. The method is capable of fabricating hollow nanotubes of various materials, and can simplify the manufacturing process, reduce the production cost of elements and increase the flexibility for selecting element materials.

The secondary objective of the present invention is to provide a method for fabricating a hollow nanotube structure by hydro-thermal growth (HTG). It can develop nanowires with a predetermined dimension at a relatively low temperature and then use the nanowires to fabricate the hollow nanotubes. Since the hydro-thermal growth can be used to fabricate the hollow nanotubes from materials without high temperature resistance, it is advantageous to produce derivative micro-electro-mechanical elements. Thus, the invention can simplify the nanotube process, decrease equipment requirements, reduce the production cost of elements, improve the dimension precision of the nanotubes, expand the applicable fields of the process, and enhance the photoelectrical properties of elements.

To achieve the above-mentioned objectives, the present invention discloses a method for fabricating the hollow nanotube structure. The method includes the steps of providing a substrate, developing a plurality of nanowires on the substrate, forming an outer covering layer on the surfaces of the nanowires, selectively etching the upper ends of the outer coating layer to expose the upper ends of the nanowires, and removing the nanowires to remain the hollow outer coating layer, which forms a plurality of hollow nanotubes

In one embodiment of the present invention, the material of the substrate is semiconductor material, glass, indium tin oxide (ITO) coated glass, ceramics, metal, polymer or sapphire.

In one embodiment of the present invention, the step of developing the nanowires on the substrate includes depositing a seed layer on the substrate, and then developing the nanowires from the seed layer.

In one embodiment of the present invention, the material of the seed layer is conductive metal material or semiconductor material with high acid and alkali resistance such as aluminum zinc oxide (AZO), indium zinc oxide (IZO), gallium zinc oxide (GZO) and zinc oxide (ZnO). The thickness of the seed layer is from 100 to 500 nanometers.

In one embodiment of the present invention, the nanowires are developed on the seed layer of the substrate by hydro-thermal growth.

In one embodiment of the present invention, the material of the nanowires is zinc oxide or nickel oxide (NiO).

In one embodiment of the present invention, the nanowires are developed from the seed layer of the substrate by hydro-thermal growth with using a mixture solution of zinc nitrate and hexamethylenetetramine (HMT). The range of the developing temperature of the nanowires is between 30 and 100° C.

In one embodiment of the present invention, the outer covering layer is formed on the surfaces of the nanowires by chemical vapor deposition (CVD), DC/RF sputter, thermal evaporation or e-beam evaporation.

In one embodiment of the present invention, the material of the nanowires is different from that of the outer covering layer.

In one embodiment of the present invention, the material of the outer covering layer is insulation material, semiconductor material, conductive material or the combination thereof. The insulation material is silicon dioxide (SiO₂), silicon nitrite (Si₃N₄), high-k dielectrics, aluminum zinc oxide (AZO), indium zinc oxide (IZO), gallium zinc oxide (GZO), indium tin oxide (ITO), nickel oxide (NiO), copper boron oxide (CuBO₂), copper aluminum oxide (CuAIO₂), copper gallium oxide (CuGaO₂), copper indium oxide (CuInO₂) or the combination thereof. The semiconductor material is silicon (Si), gallium arsenide (GaAs), lanthanum hafnium oxide (HfLaO), titanium silicide (TiSi₂), titanium nitrite (TiN), tantalum nitride (TaN) or their combinations. The conductive material is gold (Au), platinum (Pt) or their combinations. The thickness of the outer covering layer is from 100 to 1,000 nanometers.

In one embodiment of the present invention, the upper ends of the outer covering layer are selectively etched by dry or wet etching. The dry etching is inductively coupled plasma etching (ICP) or reactive ion etching (RIE). The wet etching is buffer oxide etching (BOE). The length of the etched portion of the upper end of the outer covering layer is from 10 to 500 nm.

In one embodiment of the present invention, the nanowires are removed by wet etching, and the chemical mixture solution used in the wet etching is preferably a phosphoric acid mixture solution.

In one embodiment of the present invention, the phosphoric acid mixture solution includes deionized water, phosphoric acid solution and hydrochloric acid solution in the proportion of 50:5:1.

### BRIEF DESCRIPTION OF THE DRAWINGS

FIGS. 1A to 1F are schematic flow charts of a method for fabricating hollow nanotube structure in accordance with a preferable embodiment of the present invention;

FIG. 2 is an electrical microscopic image (30,000×) of the ZnO nanowires formed by hydro-thermal growth in accordance with the preferable embodiment of the present invention;

FIG. 3 is an electrical microscopic image 10,000× of the ZnO nanowires coated with the SiO₂ outer covering layer by chemical vapor deposition (CVD) in accordance with the preferable embodiment of the present invention;

FIGS. 4A and 4B are electrical microscopic images (10,000×) in side- and top-view, respectively, showing inductively coupled plasma is used to etch the upper ends of the SiO₂ outer covering layer to expose the upper ends of the ZnO nanowires;

FIGS. 5A and 5B are electrical microscopic images (30,000×) in side- and top-view, respectively, showing the phosphoric acid/hydrochloric acid mixture solution is used to remove the ZnO nanowires for forming the hollow SiO₂ nanotube structure;

FIGS. 6A to 6C are the analysis charts (X axis represents energy in kV unit and Y axis represents strength in arbitrary unit (a.u.)) of the material properties by energy dispersive spectrum (EDS) in different process steps in accordance with the preferable embodiment of the present invention, wherein FIG. 6A is a analysis chart corresponding to the ZnO nanowires 2 as shown in FIG. 1C, FIG. 6B is a analysis chart corresponding to the SiO₂ outer covering layer 3 with the exposed upper ends and the ZnO nanowires 2 as shown in FIG. 1E, and FIG. 6C is a analysis chart corresponding to the hollow SiO₂ nanotubes 3′ as shown in FIG. 1F; and

FIG. 7 is the analysis chart (X axis represents wavelength in um unit and Y axis represents light transmission rate in %) for measuring the light transmission property of the product in different process steps in accordance with the preferable embodiment of the present invention, wherein the curve (a) corresponds to the ZnO nanowires 2 as shown in FIG. 1C., the curve (b) corresponds to the SiO₂ outer covering layer 3 with the exposed upper ends and the ZnO nanowires 2 as shown in FIG. 1E and the curve (c) corresponds to the hollow SiO₂ nanotubes 3′ as shown in FIG. 1F.

### DETAILED DESCRIPTION OF THE INVENTION

The present invention will be apparent from the following detailed description, which proceeds with reference to the accompanying drawings, wherein the same references relate to the same elements.

The present invention relates to a method for fabricating a hollow nanotube structure with different physical and chemical properties by forming nanowires and an outer covering layer. The fabricated nanotube structure can be applied to manufacturing micro-electro-mechanical and detecting elements with various functions such as light transmission materials for different kinds of photoelectric elements. For example, the photoelectric elements can be photo detectors, solar cells, LCDs and LEDs. It presents huge business opportunities and application potential in the photoelectric industry.

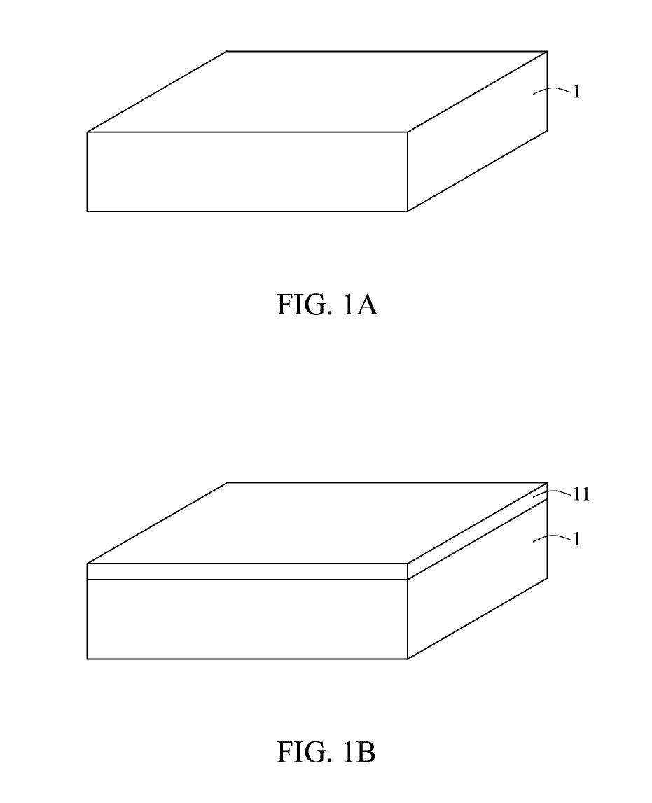

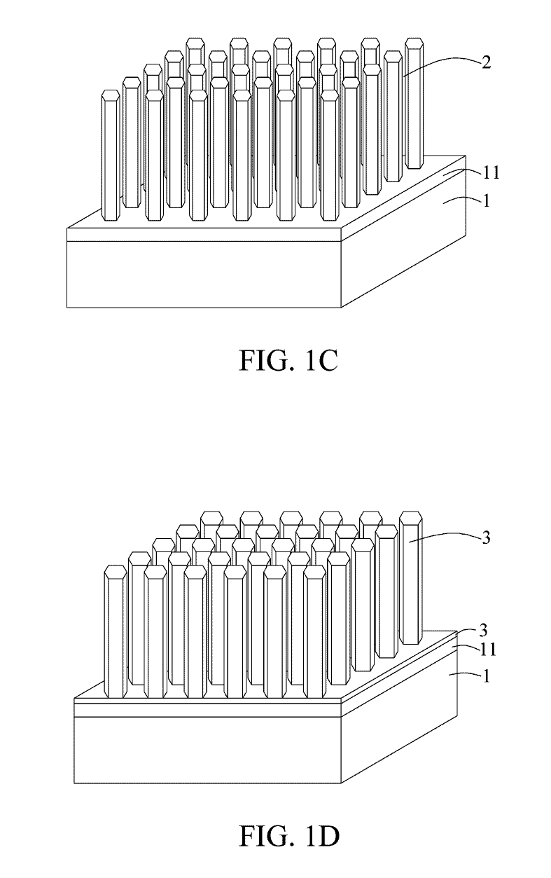

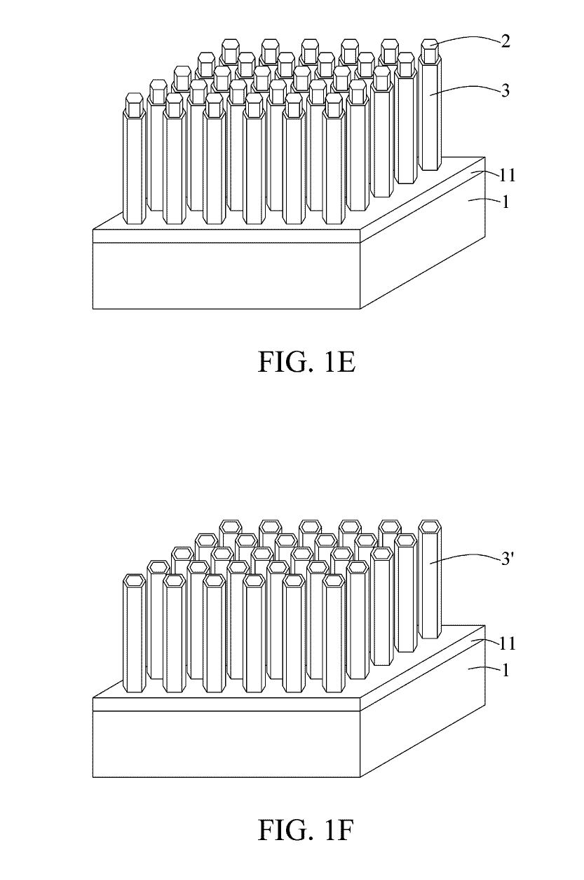

In one preferred embodiment of the present invention, the method for fabricating the hollow nanotube structure includes the main steps of providing a substrate 1, developing a plurality of nanowires 2 on the substrate 1, forming an outer covering layer 3 on the surfaces of the nanowires 2, selectively etching the upper end of the outer coating layer 3 to expose the upper ends of the nanowires 2, and removing the nanowires 2 to remain the hollow outer coating layer 3 to form a plurality of hollow nanotubes 3′. The details of each steps of the method for fabricating the hollow nanotube structure of the present invention would be further described in the following in sequence with reference to FIGS. 1A to 1F.

As shown in FIG. 1A, the first step of the method for fabricating the hollow nanotube structure in accordance with the preferred embodiment of the present invention is to provide a substrate 1. In this step, the material of the substrate 1 can be properly selected depending on the requirements of final micro-electro-mechanical or detecting elements. The material of the substrate can be, for example but not limited to, P- or N-type semiconductor material, glass, ceramics, metal, polymer or sapphire.

In the present embodiment, the substrate 1 is a glass substrate and preferably a transparent conductive coated glass (substrate) such as indium tin oxide (ITO) coated glass (substrate), which is advantageous for the subsequent production of photoelectric elements. Besides the above-mentioned rigid substrates, the substrate 1 can be a flexible substrate as well depending on the requirements of final micro-electro-mechanical or detecting elements. The flexible plastic substrate is composed of, for example, polycarbonate, polyimide, polyethylene terephthalate (PET) or other equivalent polymers.

Additionally, as shown in FIG. 1A, before the second step, the substrate 1 is preferably processed with a cleaning procedure including the following steps of washing the substrate 1 with deionized water for 5 minutes, soaking the substrate 1 in sulfuric acid/hydrogen peroxide mixture aqueous solution (H₂SO₄:H₂O₂=3:1) for 10 minutes, washing the substrate 1 with deionized water for 5 minutes, soaking the substrate 1 in hydrofluoric acid aqueous solution (HF:H₂O=1:100) for 20 seconds, washing the substrate 1 with deionized water for 5 seconds, soaking the substrate 1 in hydrochloric acid/hydrogen peroxide aqueous mixture solution (HCl:H₂O₂:H₂O=1:1:6) for 10 minutes, washing the substrate 1 with deionized water for 5 minutes, soaking the substrate 1 in hydrofluoric acid aqueous solution (HF:H₂O=1:100) for 15 to 20 seconds, washing the substrate 1 with deionized water for 5 seconds, and drying the substrate 1 with nitrogen (N₂).

As shown in FIGS. 1B and 1C, the second step of the method for fabricating the hollow nanotube structure in accordance with the preferable embodiment of the present invention is to develop a plurality of nanowires 2 on the substrate 1. In this step, the nanowires 2 are preferably developed on a seed layer 11, which is pre-deposited on the substrate 1 by hydro-thermal growth (HTG). As shown in FIG. 1B, the material of the seed layer 11 can be conductive metal material or semiconductor material with high acid and alkali resistance such as aluminum zinc oxide (AZO), indium zinc oxide (IZO), gallium zinc oxide (GZO), zinc oxide (ZnO) or others.

In this embodiment of the present invention, the aluminum zinc oxides (AZO) are used for developing the seed layer 11, and the deposition system is DC/RF sputter system or evaporation system. In addition, operation conditions of the deposition are preferably as follow: a power of 200 W, a deposition rate of 0.4 Å/sec, a vacuum of 7.6×10⁻³ torr and Argon (Ar) gas flow rate of 24 sccm. The deposition thickness of the seed layer 11 is preferably from 100 to 500 nanometers.

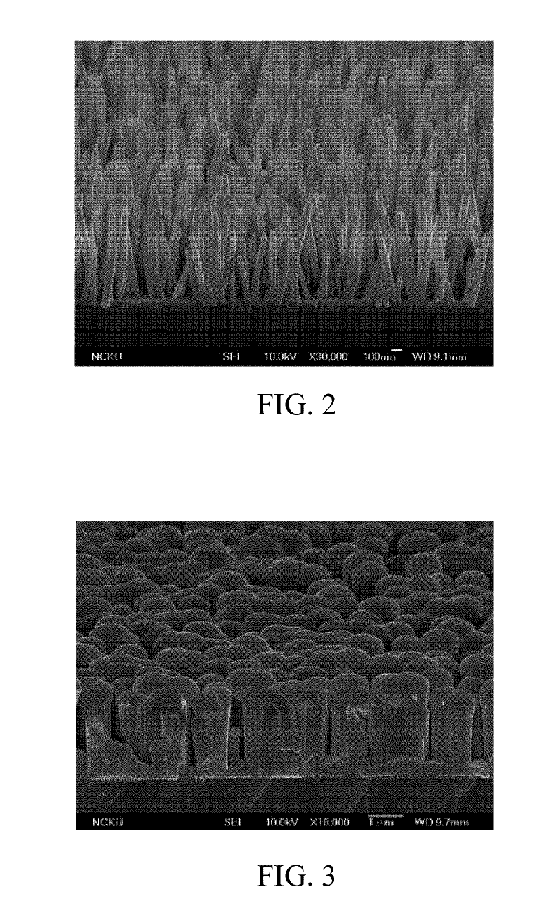

As shown in FIGS. 1C and 2, the nanowires 2 are developed on the seed layer 11 of the substrate 1 with a mixture solution of zinc nitrate and hexamethylenetetramine (HMT) during the process of hydro-thermal growth. The material of the nanowires is zinc oxide (ZnO) or nickel oxide (NiO). The developing period of the nanowires 2 is between 10 and 240 minutes and preferably between 60 and 120 minutes. The range of the developing temperature of the nanowires is between 30 and 100° C. and preferably between 85 and 95° C.

In this embodiment of the present invention, the nanowires 2 are developed by using zinc oxides. The mixture solution is prepared by solving zinc nitrate 6 g and hexamethylenetetramine 3 g in deionized water 800 ml. The substrate 1 is statically disposed in the mixture solution for about 40 to 80 minutes, and the developing temperature is controlled at about 85° C. Accordingly, as shown in FIG. 2, the zinc oxide nanowires (ZnO-NWs) 2 with vertical alignment can be developed on the seed layer 11 of the substrate 1. The diameter of the nanowires is from about 40 to 200 nm, and the length of the nanowires is from about 1 to 2 μm. The nanowires 2 are developed along the vertical direction of the surface of the substrate 1.

To be noted, the temperature for hydro-thermal growth used in the present invention is relatively low such that it prevents damaging or influencing the photoelectric properties of the derivative elements. In the present invention, the diameter and the length (height) of the nanowires can be controlled by adjusting the developing period, so that the dimension parameters such as aspect ratio, uniformity or density can be controlled. The aforementioned diameter and length are not limited and can be adjusted depending on the requirements of final micro-electro-mechanical or detecting elements.

As shown in FIG. 1D, the third step of the method for fabricating the hollow nanotube structure is to form an outer covering layer 3 on the surfaces of the nanowires 2. In this step, the outer covering layer 3 can be formed on the surfaces of the nanowires 2 by chemical vapor deposition (CVD), DC/RF sputter, thermal evaporation or e-beam evaporation. The material of the nanowires 2 should be different from that of the outer covering layer 3 in order to facilitate selective etching in the following step.

The outer covering layer 3 can be formed of a variety of source materials. Insulation materials, semiconductor materials, conductive materials and the combination thereof capable of being deposited, sputtered and evaporated can be used for forming the outer covering layer. For example, the insulation material can be silicon dioxide (SiO₂), silicon nitrite (Si₃N₄), high-k dielectrics, aluminum zinc oxide (AZO), indium zinc oxide (IZO), gallium zinc oxide (GZO), indium tin oxide (ITO), nickel oxide (NiO), copper boron oxide (CuBO₂), copper aluminum oxide (CuAIO₂), copper gallium oxide (CuGaO₂), copper indium oxide (CuInO₂) or the combination thereof. The semiconductor material can be silicon (Si), gallium arsenide (GaAs), lanthanum hafnium oxide (HfLaO), titanium silicide (TiSi₂), titanium nitrite (TiN), tantalum nitride (TaN) or the combination thereof. The conductive material can be gold (Au), platinum (Pt) or the combination thereof. The thickness of the outer covering layer 3 is from 100 to 1,000 nanometers.

As shown in FIG. 1D and FIG. 3, in the present embodiment, the material of the outer covering layer 3 is preferably silicon dioxide (SiO₂). The SiO₂ outer covering layer 3 can be covered on the surfaces of the nanowires 2 by CVD, and the final average deposition thickness of the outer covering layer 3 is about 1,000 nm (1 nm). The outer covering layer 3 can completely cover both of the surfaces of the nanowires 2 and the seed layer 11. To be noted, the deposition thickness of the outer covering layer 3 can be controlled by adjusting the parameters of the CVD process such as deposition period or deposition rate. Consequently, the thickness of the tube wall of the derivative hollow nanotubes 3′ can be controlled.

As shown in FIG. 1E, the fourth step of the method for fabricating the hollow nanotube structure in accordance with the preferable embodiment of the present invention is selectively etching the upper end of the outer coating layer 3. Since the material of the outer covering layer 3 is SiO₂, the preferable dry etching is, for example but not limited to, inductively coupled plasma etching or reactive ion etching, and the preferable wet etching is, for example but not limited to, buffer oxide etching.

The aforementioned selective etching could be various depending on the material of the outer covering layer 3. While the inductively coupled plasma etching is used, the operation conditions of the etching is preferably as follow: a RF power of 80 W, an inductively coupled plasma (ICP) power of 2,500 W, a etching rate of 45 Å/sec, a vacuum of 7.5×10⁻⁹ torr, and C₄F₈ gas flow rate of 45 sccm. The etched length of the upper ends of the outer covering layer is from 10 to 500 nanometers and preferably from 100 to 500 nm.

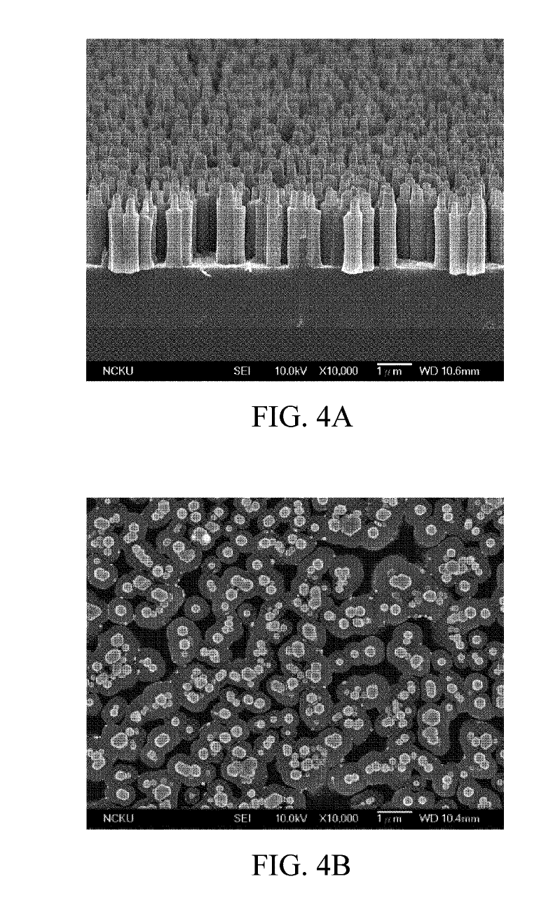

As shown in FIGS. 1E, 4A and 4B, in the present embodiment, the SiO₂ outer covering layer 3 is processed by inductively coupled plasma with aforementioned conditions. Only a predetermined length (e.g. 5 μm) of the upper end of the outer covering layer 3 is etched away by inductively coupled plasma to expose the upper ends of the nanowires 2. The length of the exposed portion of the nanowires 2 substantially corresponds to that of the etched portion of the outer covering 3.

Accordingly, the final length of the derivative hollow nanotubes 3′ is determined by the remaining length of the outer covering layer 3. In other words, the etched length of the upper ends of the outer covering layer 3 and the final length of the derivative hollow nanotubes 3′ can be determined by the condition control of the etching process. In addition, the remaining outer covering layer 3 on the surface of the seed layer 11 could be simultaneously etched and removed by using different conditions in the fourth step. However, the remaining outer covering layer 3 could be remained on the surface of the seed layer 11 if necessary.

As shown in FIG. 1F, the fifth step of the method for fabricating the hollow nanotube structure in accordance with the preferable embodiment of the present invention is removing the nanowires 2 to remain the hollow outer coating layer 3 to form a plurality of hollow nanotubes 3′. In this step, the nanowires 2 are removed by wet etching. In more detailed, the nanowires 2 are treated and etched by a proper chemical mixture solution selected depending on the material of the nanowires 2. For example, since the material of the nanowires 2 is zinc oxide or nickel oxide, the preferred chemical mixture solution is phosphoric acid mixture solution. The formula of the phosphoric acid mixture solution includes deionized water, phosphoric acid solution and hydrochloric acid solution in the proportion of 50:5:1. In addition, the nanowires 2 are etched in room temperature for 5 to 10 minutes.

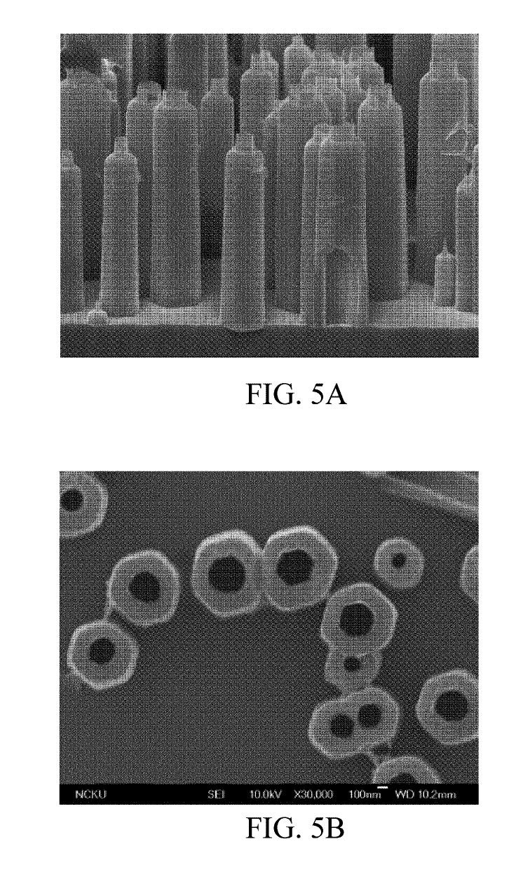

As shown in FIGS. 1F and 5, the phosphoric acid mixture solution is prepared by mixing deionized water 500 ml, phosphoric acid 50 ml and hydrochloric acid 10 ml, and then the processed substrate 1, which is processed by the fourth step, is soaked in the phosphoric acid mixture solution in room temperature for 5 to 10 minutes. Consequentially, the exposed upper ends of the nanowires 2 are firstly etched away, and then the rest of the nanowires 2 inside the outer covering layer 3 as well. Until each nanowire 2 is removed, the remaining hollow outer covering layer 3 is formed.

Accordingly, the hollow nanotubes 3′ of the present invention can be obtained preliminarily. As shown in FIG. 5, few burrs might be formed at the opening of upper ends of the hollow nanotubes 3′ because the selective etching in the fourth step. These burrs can be prevented by the condition adjustment of the selective etching in the fourth step. However, the aforementioned burrs might be remained on purpose for the application of some micro-electro-mechanical elements with particular requirements.

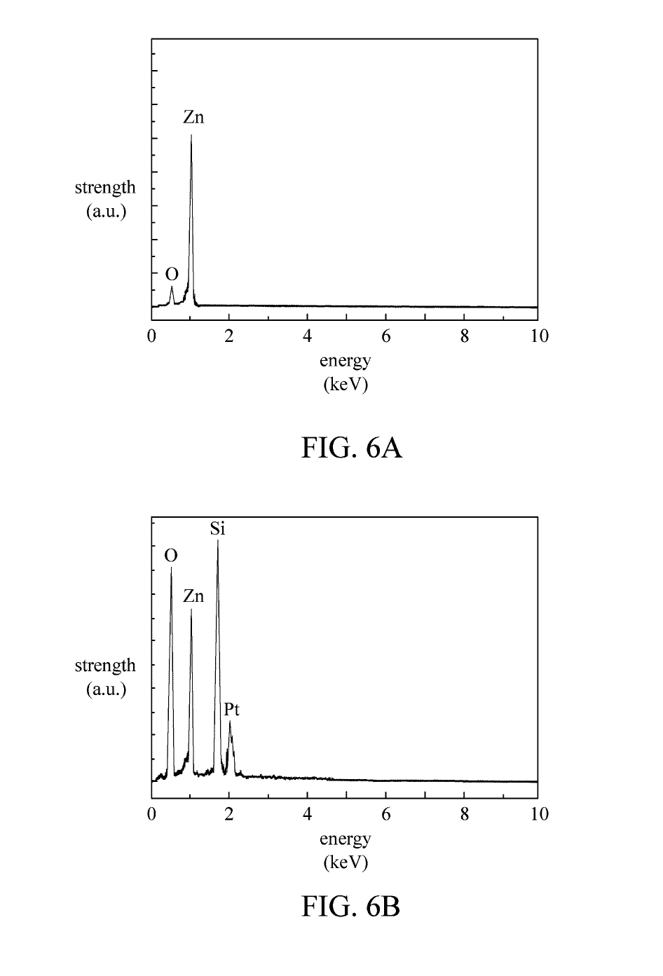

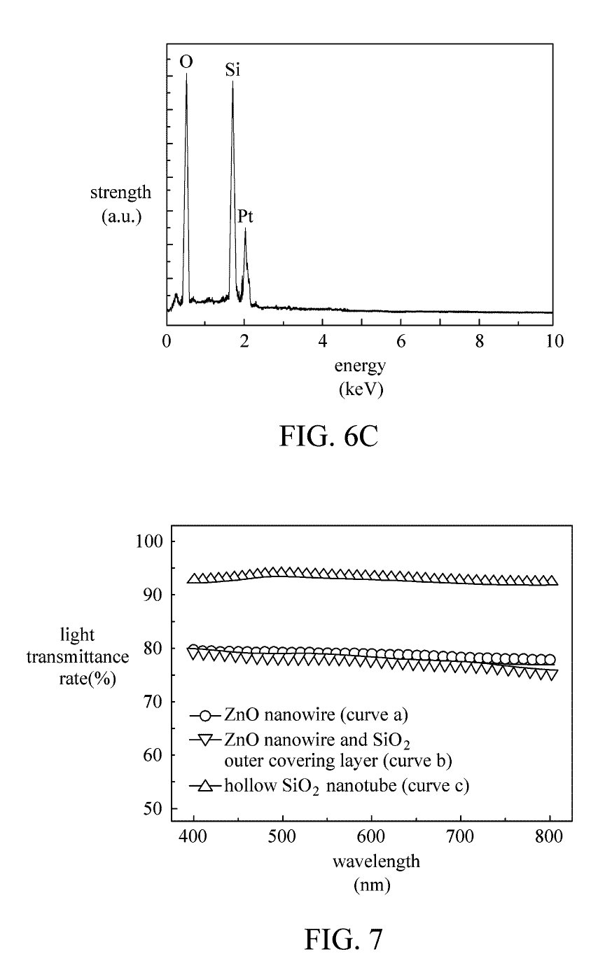

FIGS. 6A, 6B and 6C are the analysis charts of the material properties by energy dispersive spectrum (EDS) during the fourth and fifth steps in accordance with the preferable embodiment of the present invention. FIG. 6A shows the analysis chart corresponding to the ZnO nanowires 2 as shown in FIG. 1C, FIG. 6B shows the analysis chart corresponding to the SiO₂ outer covering layer 3 with the exposed upper ends and the ZnO nanowires 2 as shown in FIG. 1E, and FIG. 6C shows the analysis chart corresponding to the hollow SiO₂ nanotubes 3′ as shown in FIG. 1F. As shown in these drawings, the in-process materials in each of the steps are ZnO, ZnO and SiO₂ and SiO₂, respectively. Meanwhile, the energy dispersive spectrum also shows a small peak with respect-to platinum (Pt). It might result from the platinum covering process for the photographic observation of a scanning electron microscope (SEM).

FIG. 7 is the analysis chart for measuring the light transmission property of the product in the second, fourth and fifth steps in accordance with the preferable embodiment of the present invention. As shown in FIG. 7, the curve (a) corresponds to the ZnO nanowires 2 shown in FIG. 1C. The average length and diameter of the ZnO nanowires 2 are 2 μm and 200 nm, respectively. The curve (b) corresponds to the SiO₂ outer covering layer 3 with the exposed upper ends and the ZnO nanowires 2 shown in FIG. 1E. The thickness of the outer covering layer 3 is 1 μm, and the length of the exposed portion of the nanowires 2 is 0.5 μm. The curve (c) corresponds to the hollow SiO₂ nanotubes 3′ shown in FIG. 1F. The average length and inner diameter of the hollow SiO₂ nanotubes 3′ are 1.5 μm and 200 nm, respectively.

As shown in FIG. 7, the average light transmittance rate of the sample of the SiO₂ nanotubes 2 is higher than 92% in the range of visible light band (from 400 to 800 nm) by using a light transmittance rate measuring apparatus. Comparing to the light transmittance rate of the samples of SiO₂ outer covering layer 3 with the exposed upper ends (about 78 to 80%) and the ZnO nanowires 2 (about 77 to 80%), that of the SiO₂ nanotubes 2 increases more than 12%. The measurement of the light transmittance property proves the huge application potential of the hollow nanotubes 3′ in accordance with the present invention for photoelectric elements.

In summary, comparing the weaknesses of the conventional method for fabricating hollow nanotubes including the drawbacks of requiring expensive equipments, time-consuming and complex manufacturing process, high production cost, products without good thermal resistance, products with improper photoelectric properties and a narrow range of options for the material of hollow nanotube structure, the advantages of the method for fabricating the hollow nanotube structure shown in FIGS. 1 to 7 in accordance with the present invention are the following:

(1) the method in accordance with the present invention can be performed without expensive equipments such as the metal-organic chemical vapor deposition (MOCVD) machines for performing the epitaxy or crystal growth process, such that the expensive equipments are not needed, thereby reducing the equipment cost and decreasing the process complexity;

(2) the process of the method in accordance with the present invention is simple and can be applied to a large area substrate, which can be cut to smaller pieces after forming the hollow nanotubes, thereby facilitating the production of micro-electro-mechanical elements and reducing the production cost relatively;

(3) the hollow nanotubes in accordance with the present invention can be developed in vertical alignment on a large area substrate without catalysts and is advantageous for forming uniform nanotubes toward a single direction such that it can improve the uniformity and the production yield of nanotubes;

(4) hydro-thermal growth used for developing the nanowires, the deposition of the outer covering layer and dry/wet etching of the method in accordance with the present invention are all low temperature processes performed in relatively low temperature such that they can prevent damaging or affecting the photoelectric properties of the derivative elements and fabricate hollow nanotubes with materials without thermal resistance to broaden the application fields of certain nanotube fabrication process and improve the photoelectric properties of products;

(5) the length, inner diameter, outer diameter and tube wall thickness of the final hollow nanotube structure can be precisely controlled in the method in accordance with the present invention by controlling the diameter and length of the nanowires by using the hydro-thermal growth, controlling the deposition thickness of the outer covering layer in the formation of the outer covering layer and controlling the parameters of the length of the exposed portion of the nanowires in selective etching such that it increases the dimension precision of the nanotube and the flexibility of the product design; and

(6) since the hollow nanotubes are formed from the nanowires and the outer covering layer in the method in accordance with the present invention, the material suitable to be deposited on the nanowires as the outer covering layer can be used to fabricate the hollow nanotube structure such that the material source of the hollow nanotube structure is not limited by the process and thereby the options of element material and the flexibility of product design can be increased as well.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A method for fabricating a hollow nanotube structure, comprising the steps of:
providing a substrate;
developing a plurality of nanowires on the substrate;
forming an outer covering layer on the surfaces of the nanowires;
selectively etching the upper end of the outer coating layer to expose the upper ends of the nanowires; and
removing the nanowires to remain the hollow outer coating layer to form a plurality of hollow nanotubes.

2. The method of claim 1, wherein the material of the substrate is selected from semiconductor material, glass, indium tin oxide (ITO) coated glass, ceramics, metals, polymer and sapphire.

3. The method of claim 1, wherein the step of developing the nanowires on the substrate comprises depositing a seed layer on the substrate, and then developing the nanowires from the seed layer.

4. The method of claim 3, wherein the material of the seed layer is conductive metal materials or semiconductor materials with high acid and alkali resistance.

5. The method of claim 4, wherein the conductive metal material or the semiconductor material with high acid and alkali resistance is selected from aluminum zinc oxide, indium zinc oxide, gallium zinc oxide and zinc oxide.

6. The method of claim 3, wherein the thickness of the seed layer is from 100 to 500 nanometers.

7. The method of claim 3, wherein the nanowires are developed on the seed layer of the substrate by hydro-thermal growth.

8. The method of claim 7, wherein the material of the nanowires is zinc oxide or nickel oxide.

9. The method of claim 8, wherein the nanowires are developed on the seed layer of the substrate by hydro-thermal growth with using a mixture solution of zinc nitrate and hexamethylenetetramine.

10. The method of claim 9, wherein the range of the developing temperature of the nanowires is between 30 and 100° C.

11. The method of claim 1, wherein the outer covering layer is formed on the surfaces of the nanowires by chemical vapor deposition, DC/RF sputter, thermal evaporation or e-beam evaporation.

12. The method of claim 1, wherein the material of the nanowires is different from that of the outer covering layer.

13. The method of claim 12, wherein the material of the outer covering layer is insulation material, semiconductor material, conductive material or their combinations.

14. The method of claim 13, wherein the insulation material is silicon dioxide, silicon nitrite, high-k dielectrics, aluminum zinc oxide, indium zinc oxide, gallium zinc oxide, indium tin oxide, nickel oxide, copper boron oxide, copper aluminum oxide, copper gallium oxide, copper indium oxide or the combination thereof, the semiconductor material is silicon, gallium arsenide, lanthanum hafnium oxide, titanium silicide, titanium nitrite, tantalum nitride or the combination thereof, and the conductive material is gold, platinum or their combinations.

15. The method of claim 1, wherein the thickness of the outer covering layer is from 100 to 1,000 nanometers.

16. The method of claim 1, wherein the upper ends of the outer covering layer is selectively etched by dry or wet etching.

17. The method of claim 16, wherein the dry etching is inductively coupled plasma etching or reactive ion etching, and the wet etching is buffer oxide etching.

18. The method of claim 1, wherein the etched length of the upper end of the outer covering layer is from 10 to 500 nanometers.

19. The method of claim 1, wherein the nanowires are removed by wet etching.

20. The method of claim 19, wherein a phosphoric acid mixture solution is used in the wet etching.
